(19) United States
(12) Patent Application Publication
(10) Pub. No.: US 2018/0226322 A1
(43) Pub. Date: Aug. 9, 2018

(54) THERMOELECTRIC BONDING FOR INTEGRATED CIRCUITS

(71) Applicant: Intel Corporation, Santa Clara, CA (US)

(72) Inventors: Chwee Lin Choong, Bayan Lepas (MY); Pooi Kit Lam, Bayan Lepas (MY)

(21) Appl. No.: 15/888,659

(22) Filed: Feb. 5, 2018

(30) Foreign Application Priority Data
Feb. 6, 2017 (MY) PI 2017700399

(51) Int. Cl. H01L 23/38; H01L 35/16; H01L 23/00; H01L 35/08; H01L 35/32; H01L 35/30; H01L 25/065; H01L 35/34

(52) U.S. Cl. CPC H01L 23/38; H01L 2225/06589; H01L 24/45; H01L 24/48; H01L 24/49; H01L 35/08; H01L 24/32; H01L 35/32; H01L 35/30; H01L 24/09; H01L 25/0657; H01L 35/34; H01L 24/73; H01L 2224/73204; H01L 2224/09519; H01L 2224/32145; H01L 2224/73257; H01L 2224/48221; H01L 2224/49112; H01L 2224/45113; H01L 2224/45193; H01L 2924/01052; H01L 2225/0651; H01L 2225/06513; H01L 35/16

(57) ABSTRACT

Techniques for thermal management of an integrated circuit die are provided. In an example, an apparatus can include a first integrated circuit die having a thermal bond pad and a plurality of active components and a pair of thermoelectric bond wires. The thermal bond pad can be electrically isolated from the plurality of active components and the pair of thermoelectric bond wires can be coupled to the thermal bond pad at a bond location.

### PRIORITY APPLICATION

This application claims the benefit of priority to Malaysian Application Serial No. PI 2017700399, filed Feb. 6, 2017, which is incorporated herein by reference in its entirety.

### TECHNICAL FIELD

The disclosure herein relates generally to integrated circuits and more particularly to techniques for thermoelectric bonding of integrated circuits

### BACKGROUND

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 illustrates generally an example system with thermoelectric bond wires.

FIGS. 2A and 2B illustrate a cross-section of example thermoelectric bond wires.

FIGS. 3A-3C illustrate generally example thermoelectric bonding techniques.

FIGS. 4A and 4B illustrate generally example thermoelectric bonding techniques for stacked integrated circuits.

FIG. 5 illustrates generally a flowchart of an example method for fabricating an integrated circuit stack using thermoelectric bond wires.

FIG. 6 illustrates generally a flowchart of an example method for operating an integrated circuit stack and thermoelectric bond wires.

FIG. 7 illustrates a system level diagram, depicting an example of an electronic device (e.g., system) including thermoelectric bonding as described in the present disclosure.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

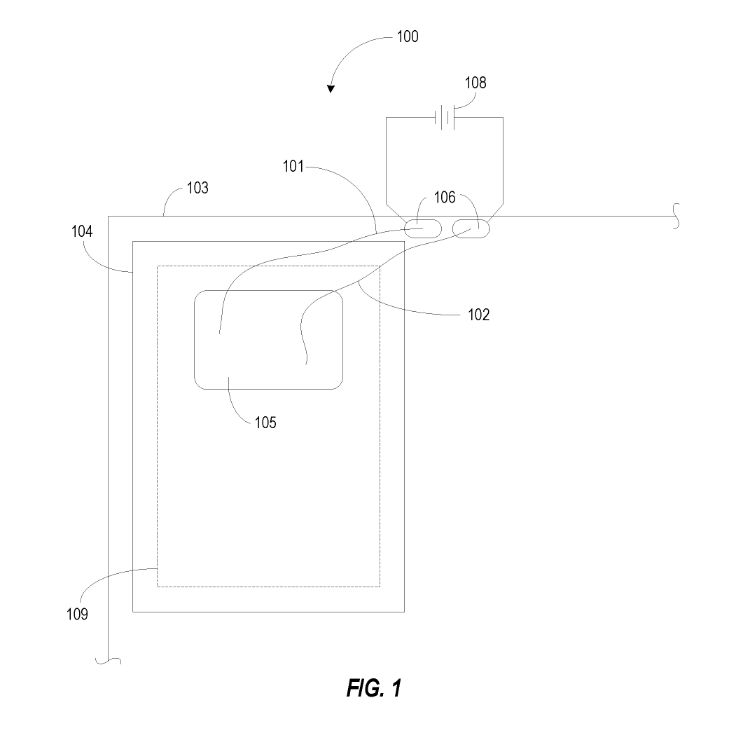

FIG. 1 illustrates generally an example system 100 using thermoelectric bond wires 101, 102. The system 100 can include a substrate 103, an integrated circuit 104, a thermal bond pad 105, a pair of thermoelectric bond wires 101, 102, a pair of substrate bond pads 106 and a voltage source 108. The integrated circuit 104 can include one or more active devices integrated on a semiconductor die 109 and packaged for installation on the substrate 103. The substrate 103, in certain examples, can be a printed circuit board, however, other substrates are possible without departing from the scope of the present subject matter. The circuit on the semiconductor die 109 can have one or more electrical connections between the active components of the circuit and the substrate 103 but those electrical connections are not shown in FIG. 1 or the other figures of this document unless specifically noted. A thermal bond pad 105 can be affixed to or integrated with the integrated circuit 104. In certain examples, the thermal bond pad 105 can be placed near a portion of the circuit that is predicted to generate a significant amount of heat. In certain examples, the thermal bond pad 105 is electrically and thermally conductive. Various metals can be used to form the thermal bond pad 105. The thermal bond pad 105 can be coupled to substrate bond pads 106 using a pair of thermoelectric bond wires 101, 102. In certain examples, the thermoelectric bond wires 101, 102 can act as a heat pump and can transfer thermal energy when used as conductors in an electrical circuit. The pair of thermoelectric bond wires 101, 102 can include a first p-type thermal bond wire 101 and a second n-type thermal bond wire 102. Such thermal bond wires 101, 102 can move thermal energy from a heat source to a heat sink using the electric current of the thermo-electric circuit formed by the voltage source 108, thermal bond wires 101, 102, the thermal bond pad 105, and the substrate bond pads 106. In certain examples, the thermo-electric circuit is electrically isolated from the circuit of the semiconductor die 109.

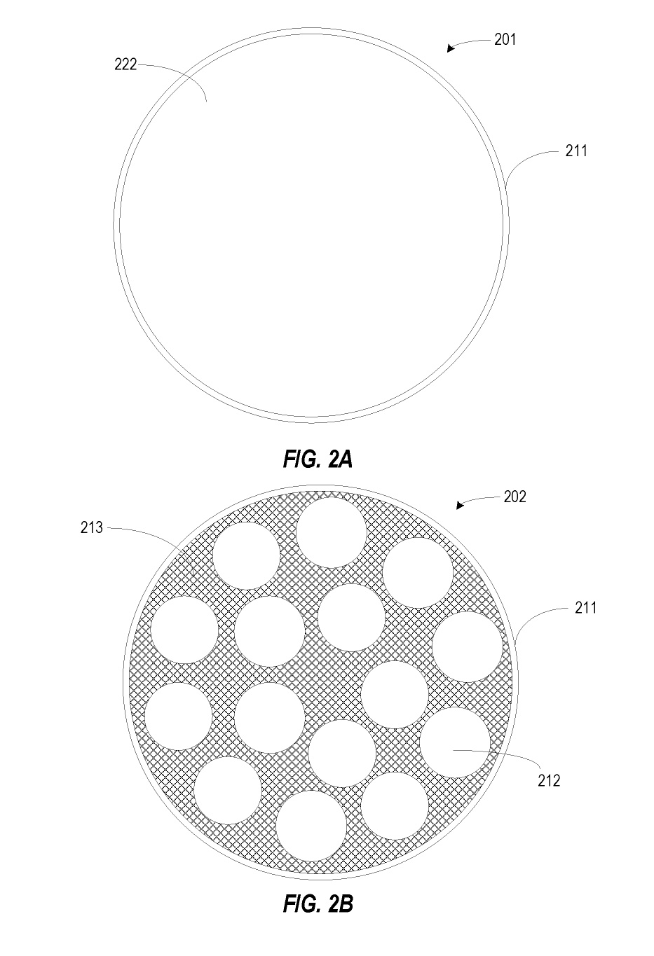

FIGS. 2A and 2B illustrate a cross-section view of example thermoelectric bond wires. FIG. 2A illustrates a solid core 222 thermoelectric bond wire 201. FIG. 2B illustrates a multiple conductor thermoelectric bond wire 202. In certain examples, each of the thermoelectric bond wires 201, 202 can include an optional exterior insulation material 211. In certain examples, the diameter of each bond wires 201, 202 can be several microns. In certain examples, the multiple conductor thermoelectric bond wire 202 can include a bundle of thermoelectric fibers 212 having a diameter of about 100 nm or less. In certain examples, an insulative material 213 can fill the gaps between the thermoelectric fibers 212. In certain examples, a solid core thermoelectric bond wire 201 or a multiple-fiber thermoelectric bond wire 202 can include a base semiconductor material such as, but not limited to, bismuth telluride. P-type thermoelectric bond wires or fibers can include or be doped with antimony. N-type thermoelectric bond wires or fibers can include or be doped with selenium. In certain examples, a p-type metallic thermoelectric bond wire can include, but is not limited to, copper, iron, chromel, a nickel-chromium alloy, or combinations thereof. In certain examples, an n-type metallic thermoelectric bond wire can include, but is not limited to, alumel, a magnetic alloy including nickel, manganese, aluminum and silicon, constantan, a nickel-copper alloy, or combinations thereof.

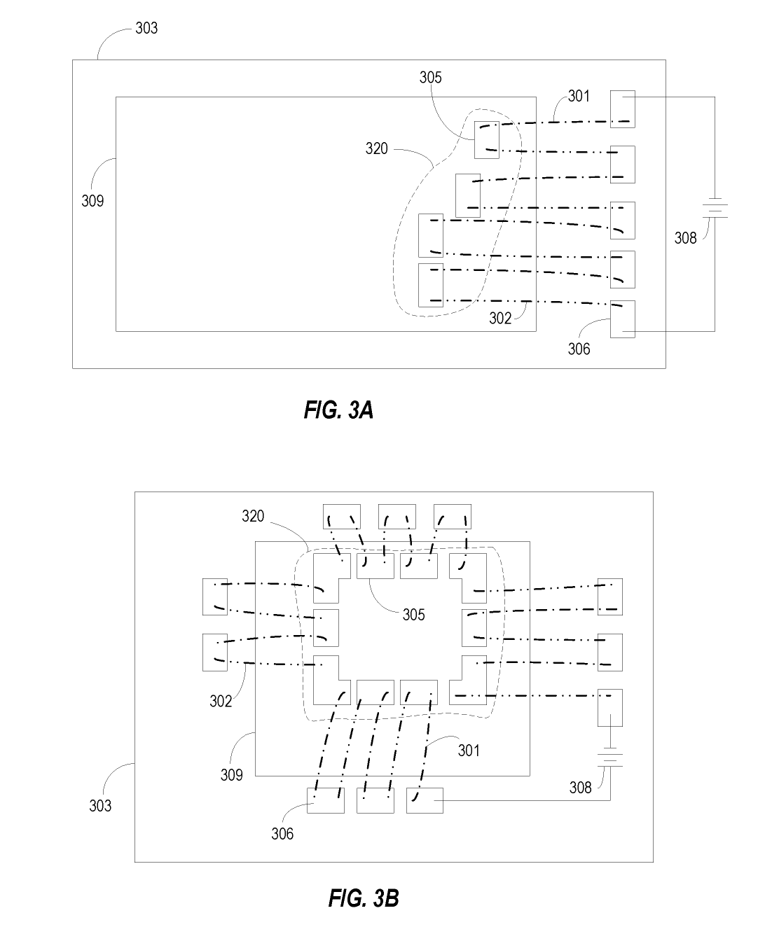

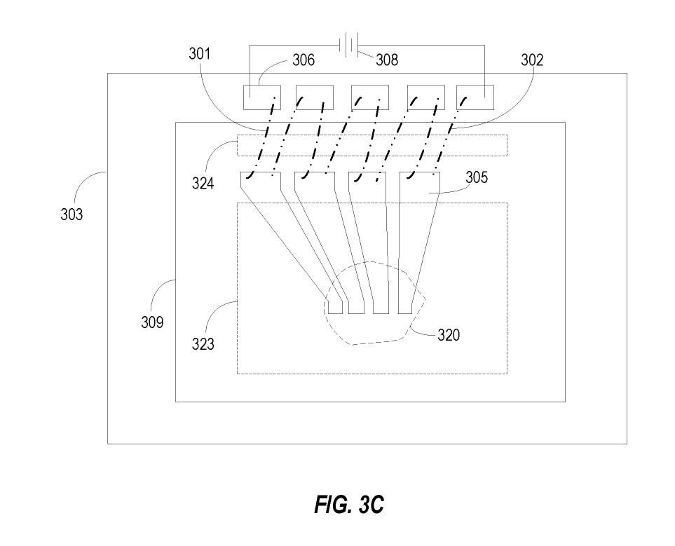

FIGS. 3A-3C illustrate generally example thermoelectric bonding techniques for transferring thermal energy with a semiconductor die. Each example can include a substrate 303, an integrated circuit on a semiconductor die 309, one or more thermal bond pads 305, one or more p-type thermoelectric bond wires 301, one or more n-type thermoelectric bond wires 302, substrate bond pads 306 and a voltage source 308. In each of FIGS. 3A-3C, an anticipated or estimated “hot-spot” 320 of the circuit of the semiconductor die is identified. The “hot-spot” 320 is an area of the circuit where cooling can be employed to remove thermal energy, for example, from the operation of active components of an integrated circuit die. Such cooling of the circuit, especially at the identified “hot-spot” 320 can allow the circuit to have a wider operating range, to be installed in a harsher environment, to prevent thermal stress across a range of operating parameters or a combination thereof.

FIG. 3A illustrates generally a configuration for arranging the thermal bond pads 305, thermoelectric conductors 301, 302, substrate bond pads 306 and the voltage source 308 to transfer thermal energy between a hot-spot 320 of a semiconductor die 309 and the substrate bond pads 306. The hot-spot 320 is located along an edge of the semiconductor die 309. A circuit including a plurality of thermal bond pads 305 and substrate bond pads 306 alternately connected in series with p-type thermoelectric bond wires 301 (dash-dot-dash) and n-type thermoelectric bond wires 302 (dash-dot-dot-dash) and a voltage source 308 allow for the thermoelectric bond wires 301, 302 to thermoelectrically transfer thermal energy between the thermal bond pads 305 and the substrate bond pads 306. In most applications, the series connections of the thermal bond pads 305, thermoelectric bond wires 301, 302 and the substrate bond pads 306 can allow heat to be transferred from the semiconductor die 309 to the substrate bond pads 306. It is understood that thermal energy can be transferred in either direction depending on the arrangement of the thermoelectric bond wires 301, 302 and polarity of the voltage source 308. In the illustrated example of FIG. 3A, the thermal bond pads 305 can be arranged in a line on the semiconductor die 309 and the substrate bond pads 306 can be arrange in a line along an edge of the substrate 303.

FIG. 3B illustrates generally a configuration for arranging the thermal bond pads 305, thermoelectric conductors 301, 302, substrate bond pads 306 and the voltage source 308 to transfer thermal energy between a hot-spot 320 of a semiconductor die 309 and the substrate bond pads 306. The hot-spot 320 is located near the center of the semiconductor die 309. A circuit including a plurality of thermal bond pads 305 and substrate bond pads 306 alternately connected in series with p-type thermoelectric bond wires 301 and n-type thermoelectric bond wires 302 and a voltage source 308 allow for the thermoelectric bond wires 301, 302 to thermoelectrically transfer thermal energy between the thermal bond pads 305 and the substrate bond pads 306. In most applications, the series connections of the thermal bond pads 305, thermoelectric bond wires 301, 302 and the substrate bond pads 306 can allow heat to be transferred from the semiconductor die 309 to the substrate bond pads 306. It is understood that thermal energy can be transferred in either direction depending on the arrangement of the thermoelectric bond wires 301, 302 and polarity of the voltage source 308. In the illustrated example of FIG. 3A, the thermal bond pads 305 can be arranged on the semiconductor die 309 around the hot-spot 320 and the substrate bond pads 306 can be arranged on the substrate 303 around the semiconductor die 309.

FIG. 3C illustrates generally a configuration for arranging the thermal bond pads 305, thermoelectric conductors 301, 302, substrate bond pads 306 and the voltage source 308 to transfer thermal energy between a hot-spot 320 of a semiconductor die 309 and the substrate bond pads 306. The hot-spot 320 can be concentrated in a smaller area near the center of the semiconductor die 309. In certain examples, the hot-spot 320 can be located over terminals, such as a ball grid array 323, for the circuit of the semiconductor die 309. In some examples, the thermal bond pads 305 and thermoelectric conductors 301, 302 can avoid other bond pad areas 324 associated with the circuit of the semiconductor die 309. A thermoelectric circuit including a plurality of thermal bond pads 305 and substrate bond pads 306 alternately connected in series with p-type thermoelectric bond wires 301 and n-type thermoelectric bond wires 302 and a voltage source 308 allow for the thermoelectric bond wires 301, 302 to thermoelectrically transfer thermal energy between the thermal bond pads 305 and the substrate bond pads 306. In most applications, the series connections of the thermal bond pads 305, thermoelectric bond wires 301, 302 and the substrate bond pads 306 can allow heat to be transferred from the semiconductor die 309 to the substrate bond pads 306. It is understood that thermal energy can be transferred in either direction depending on the arrangement of the thermoelectric bond wires 301, 302 and polarity of the voltage source 308. In the illustrated example of FIG. 3C, the thermal bond pads 305, in addition to conducting thermal energy between the hot-spot 320 and the thermoelectric bond wires 301, 301, can also conduct the thermal energy from the hot-spot to a bond location remote from the hot-spot 320. Such thermal bonding pads 305 can assist in moving thermal energy, for example, from a concentrated hot-spot 320 to more conveniently spaced bonding locations.

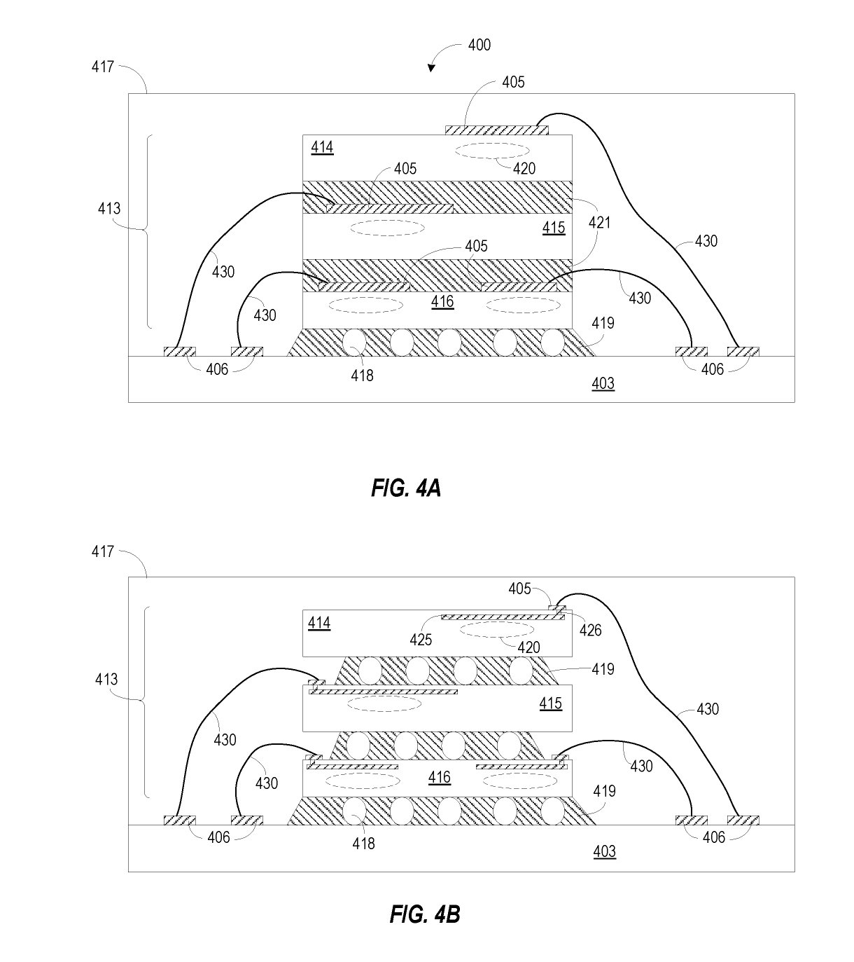

FIGS. 4A and 4B illustrate generally cross-section views of example thermoelectric bonding techniques for a stacked integrated circuit package 400. Each package 400 can include a substrate 403, a stack 413 of integrated circuit dies 414, 415, 416, and thermoelectric heat pumps 405, 430, 406 coupled to each integrated circuit dies 414, 415, 416 of the stack 413. In certain examples, the package 400 can include an encapsulant 417 to enclose and protect the integrated circuits dies 414, 415, 416 of the stack 413 and other apparatus of the package 400. In certain examples, the thermoelectric heat pumps 414 can include a thermal bond pad 405 attached to an integrated circuit, a pair of thermoelectric bond wires 430, a substrate bond pad 406 and a voltage source (not shown). In certain examples, the integrated circuits of the stack 413 of the integrated circuit dies 414, 415, 416 can be electrically coupled to the substrate via solder balls 418 or other appropriate structure. In certain examples, the stack 413 can be mechanically coupled to the substrate via under-fill material 419. The present inventors have recognized that the thermoelectric heat pumps 414 are well suited for dissipating heat generated by underlying integrated circuit dies 414, 415 of the stack 413 because the thermal bond pads can conduct the heat to bond locations where the pair of thermoelectric bond wires 430 can then thermoelectrically transfer the heat energy to a heat sink, such as the substrate bond pads 406 or metal material or layers that can spread the thermal energy quickly and are coupled to the substrate bond pads 406.

FIG. 4A illustrates generally an example package that includes surface-exposed thermal bond pads 405. In certain examples, the thermoelectric bond wires can be bonded directly to each of the thermal bond pads 405 that are fully exposed at a surface of the integrated circuit die package. As the integrated circuits dies 414, 415, 416 are stacked, the pair of thermoelectric bond wires 430 can be bonded to the thermal bond pads 405 of the integrated circuit die 414, 415, 416. If the stack 413 is already mounted to the substrate 403, the thermoelectric bond wires 430 can be bonded to the appropriate substrate bond pad 406. In certain examples, the integrated circuits dies 414, 415, 416 can be mechanically attached to each adjacent die of the stack 413 using a die attach film 421. In certain examples, the die attach film can secure at least a portion of the thermoelectric bond wires to prevent damage due to wire motion and fatigue. In certain examples, each thermal bond pad 405 can be configured to route thermal energy from a hot-spot 420 of a particular integrated circuit die, an adjacent integrated circuit die, or both a particular integrated circuit die and an adjacent integrated circuit die, to one or more thermoelectric bond wire bonding locations. In certain examples, multiple pairs of thermoelectric bond wires 430 associated with one or more stacks 413 of integrated circuit dies can be arranged in a series connected circuit as discussed above with respect to FIGS. 3A-3C to transfer thermal energy from the integrated circuit dies to heat sinks such as the substrate bond pads 406 or other heat sink apparatus.

FIG. 4B illustrates generally an example package that includes integrated thermal bond pads 405. In certain examples, thermal conductors 425, similar to thermal bond pads 405, associated with an integrated circuit die can be integrated with the die during fabrication such as via a back metal layer of the integrated circuit die. In some examples, the thermal conductor 425 is not exposed at an external surface of the integrated circuit die package, but are internal to the integrated circuit die structure. The thermal conductors 425 are electrically isolated from the active components of each of the integrated circuit die 414, 415, 416. In such examples, metal or other thermal vias 426 can couple the thermal conductors 425 to a thermal bond pad 405 at an external surface of the integrated circuit die. In certain examples, the pair of thermoelectric bond wires 430 can be bonded directly to each of the thermal bond pads 405. As the integrated circuits dies 414, 415, 416 are stacked, the pair of thermoelectric bond wires 430 can be bonded to the thermal bond pads 405 of the integrated circuit dies 414, 415, 416. If the stack 413 is already mounted to the substrate 403, the thermoelectric bond wires 430 can be bonded to the appropriate substrate bond pad 406. In certain examples, the integrated circuits of the integrated circuit dies 414, 415, 416 of the stack 413 can be electrically coupled to adjacent integrated circuit dies of the stack 413 via solder balls 418 or other appropriate structure. In certain examples, the integrated circuits dies 414, 415, 416 can be mechanically attached to each adjacent die of the stack 413 or encapsulated using an underfill 419. In certain examples, each thermal conductor 425 can be configured to route thermal energy from a hot-spot 420 of a particular integrated circuit die, an adjacent integrated circuit die, or both a particular integrated circuit die and an adjacent integrated circuit die, to one or more thermoelectric bond wire bonding locations. In certain examples, multiple pairs of thermoelectric bond wires 430 associated with one or more stacks 413 of integrated circuit dies can be arranged in a series connected circuit as discussed above with respect to FIGS. 3A-3C to transfer thermal energy from the integrated circuit dies to heat sinks such as the substrate bond pads 406 or other heat sink apparatus.

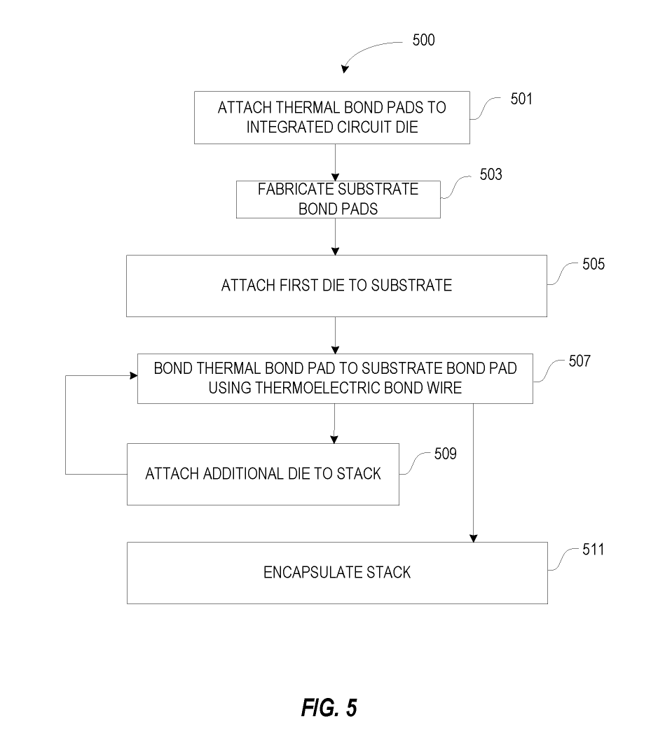

FIG. 5 Illustrates generally a flowchart of an example method for fabricating a package of stacked integrated circuit dies using thermoelectric bond wires. At 501, thermal bond pads are fabricated with one or more integrated circuit dies of the package. The thermal bond pads are shaped and positioned on the integrated circuit die to remove thermal energy from anticipated or designed hot-spots on the die. In certain examples, the thermal bond pads are exposed at a surface of the integrated circuit die. In some examples, the thermal bond pads can be coupled to thermal conductors that are not exposed at a surface of the integrated circuit die. At 503, substrate bond pads can be fabricated with the substrate. The position and shape of the substrate bond pads are configured to receive and absorb thermal energy. At 505, a first integrated circuit die can be attached to the substrate. In certain examples, the first integrated circuit die can be flip-chip attached to the substrate and further attached using underfill or a die attach film or film over wire technique. In some examples, the first integrated circuit die can be electrically wire-bonded to the substrate. At 507, thermal bond pads of the first integrated circuit die can be bonded to one or more substrate bonding pads using thermoelectric bonding wires. At 509, additional integrated circuit dies can be stacked on the first integrated circuit die. Attaching the additional integrated circuit dies can include mechanical and electrically connecting each addition integrated circuit die to the stack or to the substrate. As each additional integrated circuit die is added, at 507, each additional thermal bond pad can be coupled to a corresponding substrate bond pad using a thermoelectric bond wire, such as one of the thermoelectric bond wires discussed above with respect to FIGS. 2A and 2B. At 511, the stack and substrate can be encapsulated, for example, by molded material, to form the package.

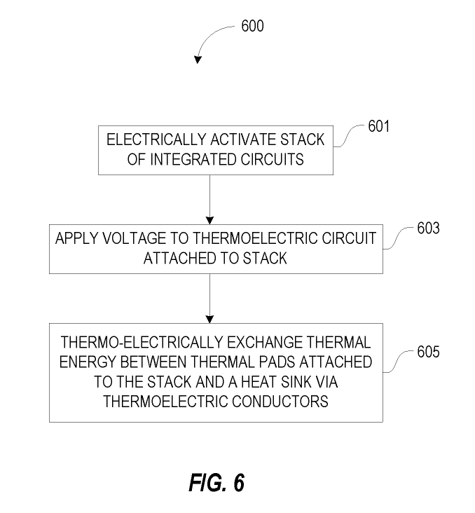

FIG. 6 illustrates generally a flowchart for an example method 600 of operating an example package. At 601, the integrated circuit of one or more stacked integrated circuit dies of the package can be electrically activated. At 603, a voltage source can be applied to a thermoelectric circuit associated with the package. The thermoelectric circuit can share a ground reference but is otherwise electrically isolated from the integrated circuits of the stack of the integrated circuit dies. At 604, in response to the applied voltage source, thermal energy from the one or more stacked integrated circuits dies can be thermoelectrically transferred from a thermal bond pad attached to one of the one or more stacked integrated circuits dies to a heat sink, such as a substrate bond pad or a cooling bond pad located on the package. The thermal energy can be conveyed via a pair of thermoelectric bond wires coupled between the thermal bond pads on or integrated with an integrated circuit die and one or more cooling bond pads such as a substrate bond pad. In certain examples, the thermal bond pads can be located on or integrated with integrated circuit dies that in the middle of the stack of integrated circuit dies.

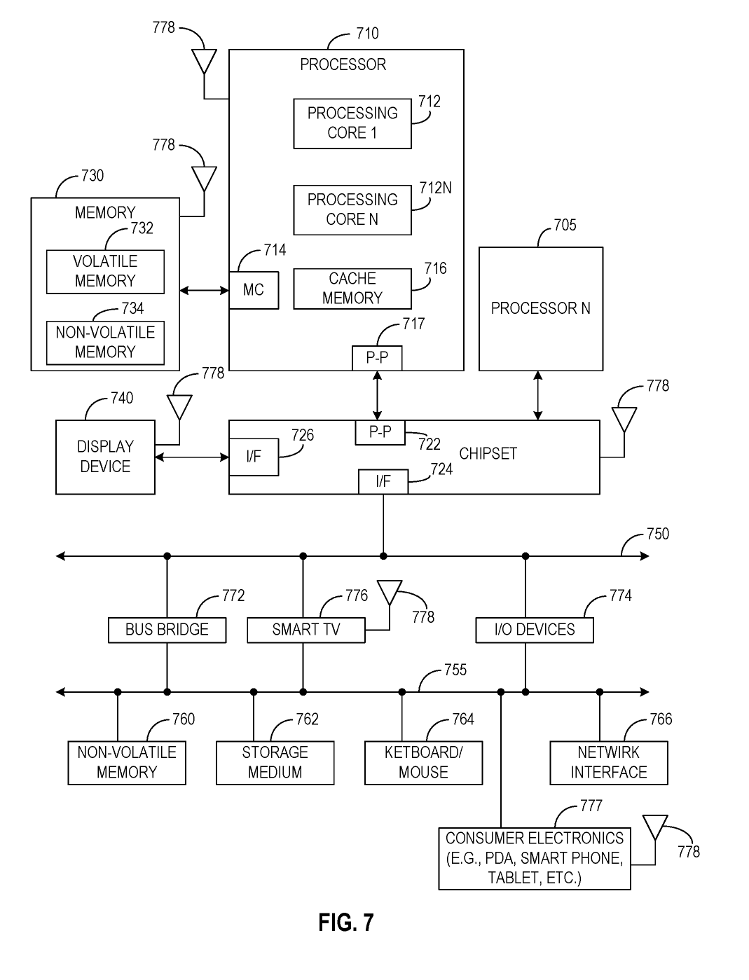

FIG. 7 illustrates a system level diagram, depicting an example of an electronic device (e.g., system) including integrated circuits with a thermoelectric bonding as described in the present disclosure. FIG. 7 is included to show an example of a higher level device application for integrated circuits with with a thermoelectric bonding. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 is a system on a chip (SOC) system.

In one embodiment, processor 710 has one or more processor cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, an interface for wireless antenna 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the example system, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices, including a bus bridge 772, a smart TV 776, I/O devices 774, nonvolatile memory 760, a storage medium (such as one or more mass storage devices) [this is the term in Fig—alternative to revise Fig. to “mass storage device(s)”—as used in para. 8] 762, a keyboard/mouse 764, a network interface 766, and various forms of consumer electronics 777 (such as a PDA, smart phone, tablet etc.), etc. In one embodiment, chipset 720 couples with these devices through an interface 724. Chipset 720 may also be coupled to a wireless antenna 778 to communicate with any device configured to transmit and/or receive wireless signals.

Chipset 720 connects to display device 740 via interface 726. Display 740 may be, for example, a liquid crystal display (LCD), a plasma display, cathode ray tube (CRT) display, or any other form of visual display device. In some embodiments of the example system, processor 710 and chipset 720 are merged into a single SOC. In addition, chipset 720 connects to one or more buses 750 and 755 that interconnect various system elements, such as I/O devices 774, nonvolatile memory 760, storage medium 762, a keyboard/mouse 764, and network interface 766. Buses 750 and 755 may be interconnected together via a bus bridge 772.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

### ADDITIONAL EXAMPLES AND NOTES

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

What is claimed is:

1. An apparatus comprising:
a first integrated circuit die including a thermal bond pad and a plurality of active components;
a pair of thermoelectric bond wires;
wherein the thermal bond pad is electrically isolated from the plurality of active components; and
wherein the pair of thermoelectric bond wires are coupled to the thermal bond pad at a bond location.

2. The apparatus of claim 1, wherein the pair of thermoelectric bond wires are configured to provide a heat pump between an area of the first integrated circuit die disposed adjacent the thermal bond pad and a heat sink when the pair of thermoelectric bond wires are coupled to a voltage source.

3. The apparatus of claim 1, wherein a first thermoelectric bond wire of the pair of thermoelectric bond wires is a p-type thermoelectric bond wire.

4. The apparatus of claim 3, wherein the first thermoelectric bond wire includes bismuth telluride.

5. The apparatus of claim 3, wherein the first thermoelectric bond wire includes bismuth telluride doped with antimony to form the p-type thermoelectric bond wire.

6. The apparatus of claim 3, wherein the first thermoelectric bond wire includes a micron-sized bismuth telluride core.

7. The apparatus of claim 3, wherein the first thermoelectric bond wire includes a bundle of nano-sized bismuth telluride fibers.

8. The apparatus of claim 3, wherein a second thermoelectric bond wire of the pair of thermoelectric bond wires is an n-type thermoelectric bond wire.

9. The apparatus of claim 8, wherein the second thermoelectric bond wire includes bismuth telluride.

10. The apparatus of claim 8, wherein the second thermoelectric bond wire includes bismuth telluride doped with selenium to form the n-type thermoelectric bond wire.

11. The apparatus of claim 8, wherein the second thermoelectric bond wire includes a micron-sized bismuth telluride core.

12. The apparatus of claim 8, wherein the second thermoelectric bond wire includes a bundle of nano-sized bismuth telluride fibers.

13. The apparatus of claim 1, wherein the first integrated circuit die is disposed in a stack with a second integrated circuit die having active components.

14. The apparatus of claim 13, wherein the metal bond pad is located between the active components of the first integrated circuit die and the active components of the second integrated circuit die.

15. The apparatus of claim 13, wherein the pair of thermoelectric bond wires are secured with die attach film disposed between the first integrated circuit die and the second integrated circuit die.

16. The apparatus of claim 1, wherein the thermal bond pad is configured to thermally conduct heat to the pair of thermoelectric bond wires from a position of the first integrated circuit die that is remote from the bond location.

17. The apparatus of claim 1, wherein the thermal bond pad is exposed at an external surface of the first integrated circuit die.

18. The apparatus of claim 1, wherein the thermal bond pad is coupled to an internal thermal conductor of the integrated circuit die, wherein the internal thermal conductor thermally is configured to conduct heat energy of the integrated circuit die.

19. A method for managing thermal energy of an integrated circuit die, the method comprising:
activating the active circuits of the integrated circuit die;
applying a voltage to a thermoelectric circuit having a thermal bond pad mechanically coupled to the integrated circuit die and a pair of thermoelectric bond wires;
thermoelectrically transferring thermal energy of the integrated circuit die using a pair of thermoelectric bond wires coupled to the thermal bond pad in response to the applied voltage.

20. The method of claim 19, wherein at least one thermoelectric bond wire of the pair of thermoelectric bond wires includes a micron-sized bismuth telluride core.

21. The method of claim 19, wherein at least one thermoelectric bond wire of the pair of thermoelectric bond wires includes a bundle of nano-sized bismuth telluride fibers.
